(19) United States
(12) Patent Application Publication
(10) Pub. No.: US 2025/0056811 A1
(43) Pub. Date: Feb. 13, 2025

(54) MEMORY DEVICE AND MANUFACTURING METHOD THEREOF

(71) Applicant: Samsung Electronics Co., Ltd., Suwon-si (KR)

(72) Inventor: Jeonil Lee, Suwon-si (KR)

(21) Appl. No.: 18/670,777

(22) Filed: May 22, 2024

(30) Foreign Application Priority Data
Aug. 10, 2023 (KR) 10-2023-0105097

(51) Int. Cl. H10B 53/30

(52) U.S. Cl. CPC H10B 53/30

(57) ABSTRACT

A memory device includes a substrate, a plurality of bit lines on the substrate and extending in a first horizontal direction and separated from each other in a second horizontal direction that intersects the first horizontal direction, a plurality of channel layers extending in a vertical direction that is perpendicular to an upper surface of the substrate on the plurality of bit lines, a plurality of word lines on one of the bit lines in the vertical direction and extending in the second horizontal direction and separated from each other in the first horizontal direction, an interlayer insulating layer between the plurality of channel layers, and a gate insulating layer between one of the channel layers and one of the word lines and on an upper surface of the interlayer insulating layer opposite the substrate.

### CROSS-REFERENCE TO RELATED APPLICATION

This application claims priority under 35 U.S.C. § 119 to Korean Patent Application No. 10-2023-0105097, filed on Aug. 10, 2023, in the Korean Intellectual Property Office, the disclosure of which is incorporated by reference herein in its entirety.

### FIELD

The inventive concept relates to a semiconductor memory device and a manufacturing method thereof.

### BACKGROUND

To meet demand for miniaturization, multi-function, and high performance of electronic products, high-capacity semiconductor memory devices have been developed, and to provide the high-capacity semiconductor memory devices, a degree of integration has been increased. Because the integration of existing two-dimensional (2D) semiconductor memory devices may be determined by an area occupied by a unit memory cell, the integration of 2D semiconductor memory devices has increased but is still limited. Accordingly, three-dimensional (3D) semiconductor memory devices in which a plurality of memory cells are stacked on a substrate in the vertical direction to increase a memory capacity have been proposed.

### SUMMARY

The inventive concept provides a memory device with improved mobility of electrons in a channel layer, improved reliability, and reduced process difficulty, and a manufacturing method thereof.

In addition, the problems to be solved by the technical idea of the inventive concept are not limited to the problems mentioned above, and the other problems could be clearly understood by those of ordinary skill in the art from the description below.

According to an aspect of the inventive concept, there is provided a memory device including a substrate, a plurality of bit lines on the substrate and extending in a first horizontal direction and separated from each other in a second horizontal direction that intersects the first horizontal direction, a plurality of channel layers extending in a vertical direction that is perpendicular to an upper surface of the substrate on the plurality of bit lines, a plurality of word lines on one of the bit lines in the vertical direction and extending in the second horizontal direction and separated from each other in the first horizontal direction, an interlayer insulating layer between the plurality of channel layers, a gate insulating layer between one of the channel layers and one of the word lines and on an upper surface of the interlayer insulating layer opposite the substrate, and a ferroelectric capacitor structure on the channel layer in the vertical direction and including a plurality of first electrodes separated from each other in the vertical direction.

According to another aspect of the inventive concept, there is provided a memory device including a substrate, a plurality of bit lines on the substrate and extending in a first horizontal direction and separated from each other in a second horizontal direction that intersects the first horizontal direction, a plurality of vertical transistors each including word lines on the plurality of bit lines in a vertical direction that is perpendicular to the substrate, the word lines extending in the second horizontal direction and separated from each other in the first horizontal direction, a channel layer extending in the vertical direction on the substrate, and a gate insulating layer between one of the word lines and the channel layer, an interlayer insulating layer between the plurality of vertical transistors, an etching stop layer on the gate insulating layer and the interlayer insulating layer, and a ferroelectric capacitor structure on each of the plurality of vertical transistors in the vertical direction and including two or more capacitors, wherein the gate insulating layer extends along an upper surface of the interlayer insulating layer and on an upper surface of the one of the word lines opposite the substrate.

According to another aspect of the inventive concept, there is provided a memory device including a substrate, a first interlayer insulating layer on the substrate, a plurality of bit lines buried in the first interlayer insulating layer, extending in a first horizontal direction, and separated from each other in a second horizontal direction that intersects the first horizontal direction, a plurality of vertical transistors including a plurality of channel layers extending in a vertical direction on a bit line among the plurality of bit lines, a word line separated from the plurality of channel layers in the first horizontal direction and extending in the second horizontal direction, and a gate insulating layer between each of the plurality of channel layers and the word line and extending along a sidewall of each of the plurality of channel layers, a second interlayer insulating layer between the plurality of vertical transistors on the bit line, an etching stop layer covering the gate insulating layer and the second interlayer insulating layer, and a plurality of ferroelectric capacitor structures on the plurality of vertical transistors in the vertical direction, each of the plurality of ferroelectric capacitor structures including a plurality of first electrodes stacked on and separated from each other on the second interlayer insulating layer in the vertical direction, a hollow ferroelectric layer conformally extending on a sidewall of a hole penetrating the plurality of first electrodes in the vertical direction, and a second electrode extending in the vertical direction inside the hollow ferroelectric layer, wherein the gate insulating layer has a first surface in contact with the bit line and a second surface opposite to the first surface and in contact with the etching stop layer, the second surface longitudinally extends in the second horizontal direction, and the second surface overlaps, in the vertical direction, the plurality of vertical transistors separated from each other in the second horizontal direction.

### BRIEF DESCRIPTION OF THE DRAWINGS

Embodiments of the inventive concept will be more clearly understood from the following detailed description taken in conjunction with the accompanying drawings in which:

FIG. 1 is an equivalent circuit diagram of a memory device according to an embodiment;

FIGS. 2 and 3 are a perspective view and a top view of a memory device according to an embodiment;

FIG. 4 illustrates cross-sectional views of the memory device taken along lines X-X′ and Y-Y′ of the top view of FIG. 3;

FIG. 5 is a magnified cross-sectional view of region A of FIG. 4;

FIG. 6 illustrates cross-sectional views of a memory device according to another embodiment, corresponding to the cross-sectional views of the memory device taken along lines X-X′ and Y-Y′ of the top view of FIG. 3;

FIG. 7 is a magnified cross-sectional view of region B of FIG. 6;

FIG. 8 illustrates cross-sectional views of a memory device according to another embodiment, corresponding to the cross-sectional views of the memory device taken along lines X-X′ and Y-Y′ of the top view of FIG. 3; and

FIGS. 9, 10A, 10B, 10C, 11A, 11B, 11C, 12A, 12B, 12C, 13A, 13B, 13C, 14A, 14B, 14C, 15A, 15B, and 15C are top views and cross-sectional views illustrating, in order, a method of manufacturing a memory device, according to an embodiment, where FIGS. 10B, 11B, 12B, 13B, 14B, and 15B are cross-sectional views of the memory device taken along line X-X′ of the top views of FIGS. 10A, 11A, 12A, 13A, 14A, and 15A, respectively, and FIGS. 10C, 11C, 12C, 13C, 14C, and 15C are cross-sectional views of the memory device taken along line Y-Y′ of the top views of FIGS. 10A, 11A, 12A, 13A, 14A, and 15A, respectively.

### DETAILED DESCRIPTION OF EMBODIMENTS

Hereinafter, embodiments are described in detail with reference to the accompanying drawings. The inventive concept may, however, be embodied in many different forms and should not be construed as being limited to the embodiments set forth herein. These embodiments are provided so that the inventive concept will be thorough and complete, and will fully convey the scope of the inventive concept to those of ordinary skill in the art. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “immediately” or “directly” on, or “in direct contact” or “directly connected,” no intervening components or layers are present.

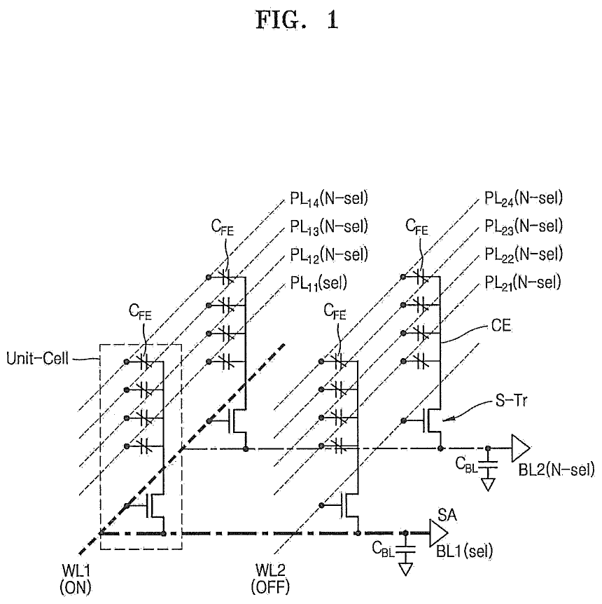

FIG. 1 is an equivalent circuit diagram of a memory device 10 according to an embodiment.

Referring to FIG. 1, the memory device 10 according to the present embodiment may include first and second bit lines BL1 and BL2, a select transistor S-Tr, and a ferroelectric capacitor (FeCap) CFE. First and second word lines WL1 and WL2 connected to the first and second bit lines BL1 and BL2 and the gate of the select transistor S-Tr may be individually two-dimensionally arranged. For example, the first and second bit lines BL1 and BL2 may extend in a first horizontal direction (the X direction) and be separated from each other in a second horizontal direction (the Y direction). In addition, the first and second word lines WL1 and WL2 may extend in the second horizontal direction (the Y direction) and be separated from each other in the first horizontal direction (the X direction). In the specification, the direction in which the first and second bit lines BL1 and BL2 extend may be defined as the first horizontal direction (the X direction), and the direction in which the first and second bit lines BL1 and BL2 are separated from each other may be defined as the second horizontal direction (the Y direction).

A plurality of select transistors S-Tr may be connected in parallel to each of the first and second bit lines BL1 and BL2. For example, the first bit line BL1 may be commonly connected to one end of the source/drain of each of select transistors S-Tr arranged on a first row in the first horizontal direction (the X direction), and the second bit line BL2 may be commonly connected to one end of the source/drain of each of select transistors S-Tr arranged on a second row in the first horizontal direction (the X direction). In addition, the first word line WL1 may be commonly connected to the gate of each of select transistors S-Tr arranged on the first row in the second horizontal direction (the Y direction), and the second word line WL2 may be commonly connected to the gate of each of select transistors S-Tr arranged on the second row in the second horizontal direction (the Y direction).

The FeCap C_{FE} may be connected to the other end of the source/drain of each of the select transistors S-Tr. As shown in the circuit diagram of FIG. 1, a plurality of FeCaps C_{FE} may be disposed in the vertical direction (the Z direction) to be connected to the source/drain of one select transistor S-Tr. For example, the plurality of FeCaps C_{FE} disposed in the vertical direction (the Z direction) may be commonly connected to a common electrode CE and respectively connected to corresponding plate line electrodes PL. In addition, a plate line electrode PL may be connected to FeCaps C_{FE} in the second horizontal direction (the Y direction) and at the same level (e.g., relative to a substrate or other frame of reference) in the vertical direction (the Z direction).

More particularly with reference to the circuit diagram of FIG. 1, when it is assumed that four FeCaps C_{FE} separated from each other in the vertical direction (the Z direction) constitute a set capacitor, set capacitors may be at the same positions as the plurality of select transistors S-Tr on the X-Y plane, respectively. In addition, first and second set plate line electrodes PL1 and PL2 respectively connected to corresponding set capacitors may extend in the second horizontal direction (the Y direction) and be separated from each other in the first horizontal direction (the X direction). Because a set capacitor incudes four FeCaps C_{FE} separated from each other in the vertical direction (the Z direction), the first set plate line electrode PL1 on a first column may include first to fourth plate line electrodes PL1 to PL14 separated from each other in the vertical direction (the Z direction), and the second set plate line electrode PL2 on a second column may include first to fourth plate line electrodes PL21 to PL24 separated from each other in the vertical direction (the Z direction).

The memory device 10 according to the present embodiment may have a structure which has the connection relationship described above, and in which a plurality of FeCaps C_{FE}, e.g., four FeCaps C_{FE}, are connected to one select transistor S-Tr. Accordingly, the memory device 10 may have a 1TnC structure in which n (n is an integer greater than or equal to 2) capacitors are connected to one transistor. As a reference, in the circuit diagram of FIG. 1, as shown with a thick dashed line and a thick alternate long and short dash line, the first bit line BL1 and the first word line WL1 may be selected to turn on a left select transistor S-Tr in the first horizontal direction (the X direction), and the first bit line BL1 and the first plate line electrode PL1 of the first set plate line electrode PL1 may be selected to store or read information in or from a corresponding FeCap C_{FE}. In case of read, a sense amplifier SA connected to the first bit line BL1 may be used. In the circuit diagram of FIG. 1, sel denotes a selected line and N-sel denotes a non-selected line.

In the memory device 10 according to the present embodiment, a plurality of FeCaps C_{FE} connected to the source/drain of a select transistor S-Tr may have a square pillar shape by being separated from each other in the vertical direction (the Z direction) and lying or extending in one direction, e.g., the first horizontal direction (the X direction). In addition, compared to a general vertical stack (VS)-dynamic random access memory (DRAM) structure, a cell transistor is not required, and thus, process difficulty/distribution may be significantly reduced.

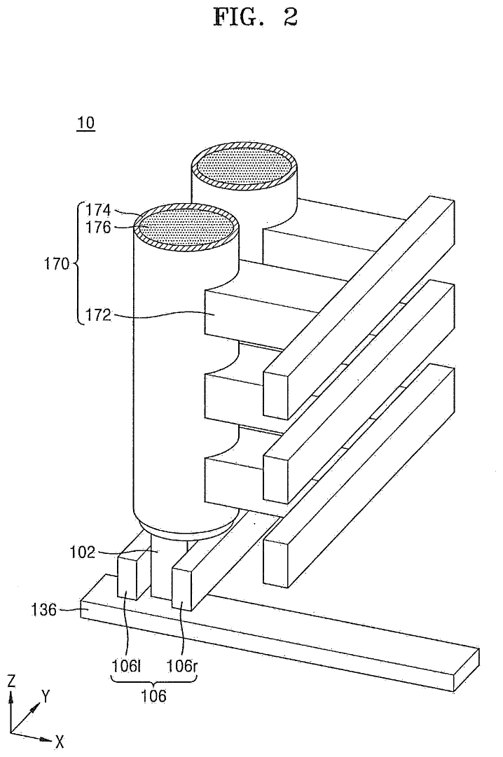

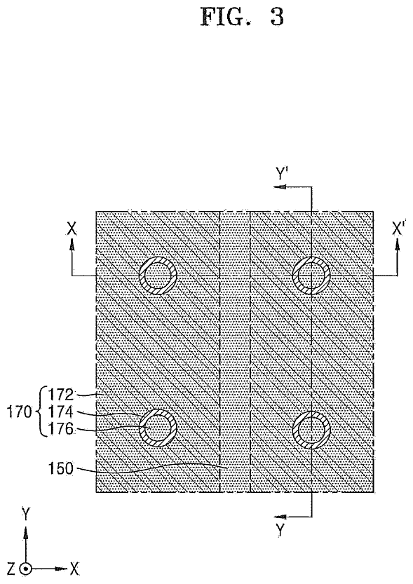

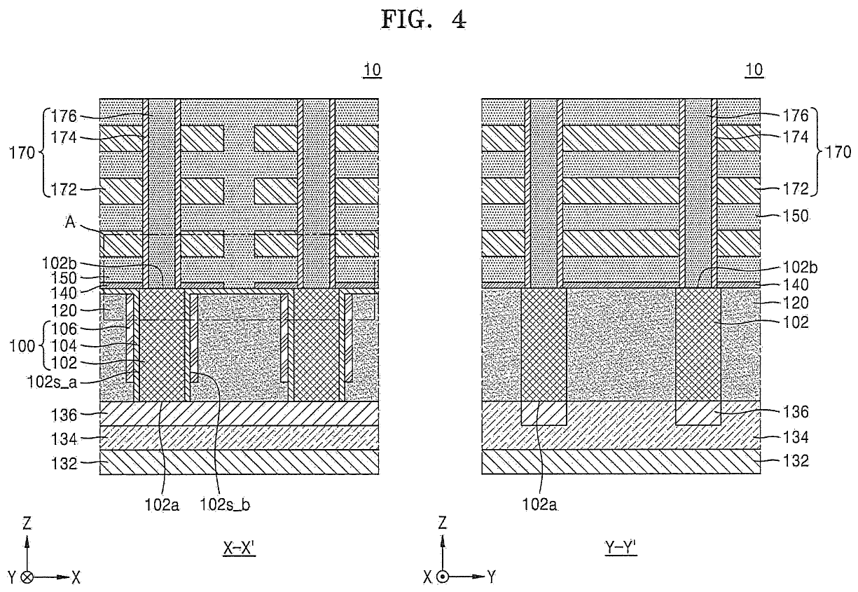

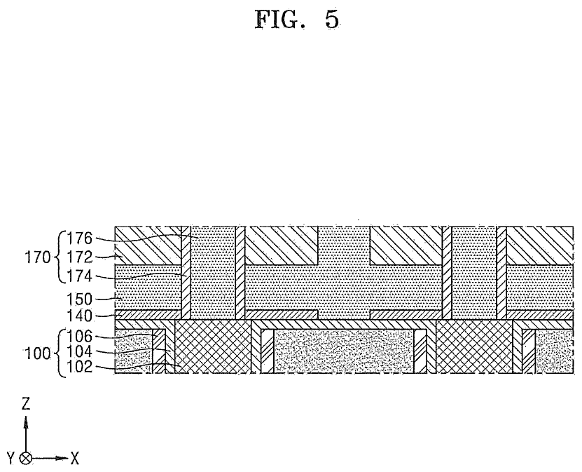

FIGS. 2 and 3 are a perspective view and a top view of the memory device 10 according to an embodiment, showing a portion corresponding to one word line in the memory device 10 of FIG. 1. FIG. 4 illustrates cross-sectional views of the memory device 10 taken along lines X-X′ and Y-Y′ of the top view shown in FIG. 3, and FIG. 5 is a magnified cross-sectional view of region A of FIG. 4. A description below is made with reference to FIG. 1 together, and the description made with reference to FIG. 1 is simply repeated or omitted.

Referring to FIGS. 2 to 5, the memory device 10 (ferroelectric RAM) according to an embodiment may include a flipped substrate 132, a first interlayer insulating layer 134, a bit line 136, a vertical transistor 100, an etching stop layer 140, an insulating layer 150, and a FeCap structure 170. The memory device 10 according to the present embodiment may have a bilaterally symmetrical structure with reference to a center line between first electrodes 172 of two FeCap structures 170 adjacent to each other in the first horizontal direction (the X direction) or a center line between second electrodes 176 of two FeCap structures 170 adjacent to each other in the first horizontal direction (the X direction).

The flipped substrate 132 may be parallel to the first horizontal direction (the X direction) and the second horizontal direction (the Y direction). The flipped substrate 132 may include silicon (Si), e.g., monocrystalline Si, polycrystalline Si (poly-Si), or amorphous Si. Of course, the material of the flipped substrate 132 is not limited to Si. For example, in some embodiments, the flipped substrate 132 may include a group IV semiconductor, such as germanium (Ge), a group IV-IV compound semiconductor, such as silicon germanium (SiGe) or silicon carbide (SiC), or a group III-V compound semiconductor, such as gallium arsenide (GaAs), indium arsenide (InAs), or indium phosphide (InP).

The flipped substrate 132 may be based on a Si bulk substrate. Alternatively, the flipped substrate 132 may be based on a silicon on insulator (SOI) substrate or a germanium on insulator (GeOI) substrate. The flipped substrate 132 is not limited to the bulk, SOI or GeOI substrate and may be a substrate based on an epitaxial wafer, a polished wafer, an annealed wafer, or the like. The flipped substrate 132 may include a conductive region, e.g., an impurity-doped well or various structures doped with impurities. In addition, the flipped substrate 132 may constitute a P-type substrate or an N-type substrate according to the type of doped impurity ions. A peripheral circuit and a wiring layer connected to the peripheral circuit may be on a partial region of the flipped substrate 132.

The first interlayer insulating layer 134 may be between the bit line 136 and the flipped substrate 132 and/or between a second interlayer insulating layer 120 and the flipped substrate 132. The first interlayer insulating layer 134 may be formed to extend along the upper surface of the flipped substrate 132. The first interlayer insulating layer 134 may include an oxide layer, e.g., a silicon dioxide (SiO₂) layer. However, the material of the first interlayer insulating layer 134 is not limited to the oxide layer. According to an embodiment, the first interlayer insulating layer 134 may include a nitride layer.

The second interlayer insulating layer 120 may be on the first interlayer insulating layer 134. The second interlayer insulating layer 120 may cover a portion of the upper surface of the first interlayer insulating layer 134 and the upper surface of the bit line 136. Particularly, the bit line 136 may extend in the first horizontal direction (the X direction) along a groove formed in the first interlayer insulating layer 134, and the second interlayer insulating layer 120 may cover the upper surface of the first interlayer insulating layer 134 except for a portion where the groove is formed. The second interlayer insulating layer 120 may include an oxide layer, e.g., a SiO₂ layer. However, the material of the second interlayer insulating layer 120 is not limited to the oxide layer. According to an embodiment, the second interlayer insulating layer 120 may include a nitride layer.

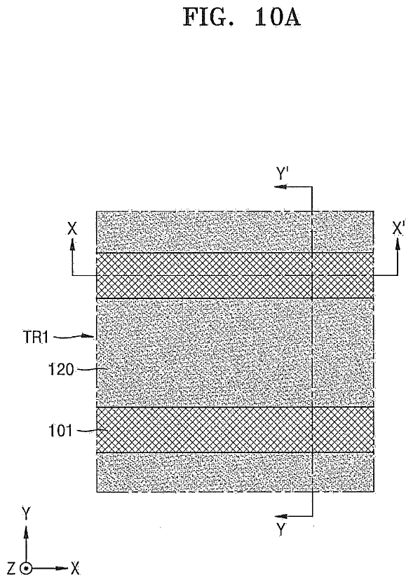

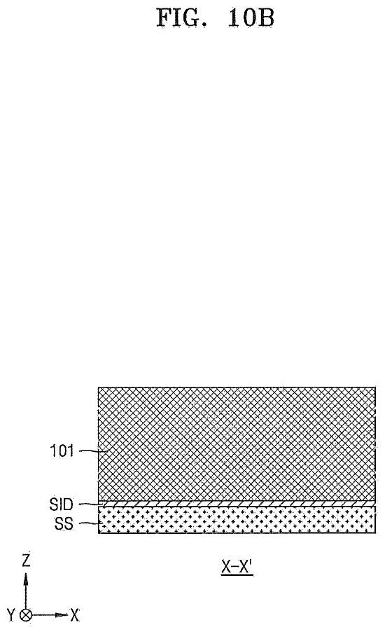

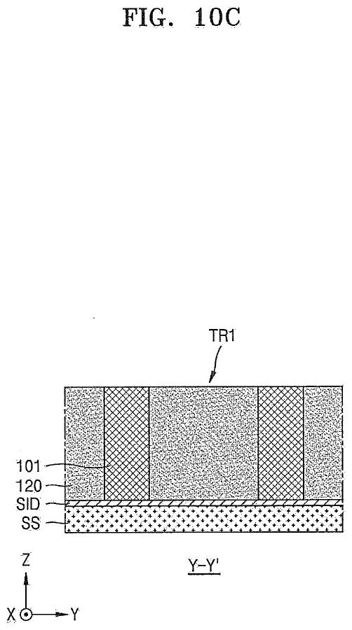

Bit lines 136 may extend in the first horizontal direction (the X direction) and be separated from each other in the second horizontal direction (the Y direction), on a monocrystalline Si wafer 101 (see FIG. 10B). The bit line 136 may be connected to a select transistor S-Tr, particularly, an impurity region (not shown) of the select transistor S-Tr. The impurity region (not shown) may correspond to a source/drain region of the select transistor S-Tr. The bit line 136 may include a conductive material. The bit line 136 may include any one of, for example, a doped semiconductor material, a metal, conductive metal nitride, and a metal-semiconductor compound. Although not particularly shown, according to an embodiment, the impurity region (not shown) may be formed on upper and lower regions of a channel layer 102 in the vertical direction (the Z direction).

Vertical transistors 100 may be on bit lines 136 at certain intervals therebetween in the first horizontal direction (the X direction) and the second horizontal direction (the Y direction). For example, vertical transistors 100 may be on the bit line 136 in the first horizontal direction (the X direction). The vertical transistor 100 may include the channel layer 102 extending on the bit line 136 in the vertical direction (the Z direction), a gate insulating layer 104 covering a first sidewall 102s_a and a second sidewall 102s_b of the channel layer 102, which intersect with the first horizontal direction (the X direction), and word lines 106 covering a portion of the gate insulating layer 104, separated from each other in the first horizontal direction (the X direction), and extending in the second horizontal direction (the Y direction).

The word lines 106 of the vertical transistor 100 may extend on both (e.g., opposing) sidewalls, i.e., the first sidewall 102s_a and the second sidewall 102s_b, of the channel layer 102 in the second horizontal direction (the Y direction). As shown in FIG. 2, the word lines 106 may include a first sub-gate electrode 106l facing the first sidewall 102s_a of the channel layer 102 and a second sub-gate electrode 106r facing the second sidewall 102s_b opposite to the first sidewall 102s_a of the channel layer 102. With one channel layer 102 is between the first sub-gate electrode 1061 and the second sub-gate electrode 106r, the vertical transistor 100 may have a dual-gate transistor structure. However, the inventive concept of the inventive concept is not limited thereto, and the vertical transistor 100 may have a single-gate transistor structure in which the second sub-gate electrode 106r is omitted and only the first sub-gate electrode 1061 facing the first sidewall 102s_a of the channel layer 102 is formed.

Although not shown, the vertical transistor 100 may include impurity regions (not shown) corresponding to a source/drain at both sides of the channel layer 102 in the vertical direction (the Z direction). The vertical transistor 100 may correspond to the select transistor S-Tr of FIG. 1. One of the impurity regions (not shown) at both sides of the channel layer 102 in the vertical direction (the Z direction) may be connected to the bit line 136, and the other impurity region (not shown) thereof may be connected to the FeCap structure 170. That is, the impurity regions (not shown) may be respectively formed on a first surface 102a and a second surface 102b of the channel layer 102.

The channel layer 102 may include monocrystalline Si. The monocrystalline Si included in the channel layer 102 has Si atoms regularly arranged, and every two Si atoms are joined with a covalent bond, and thus, the monocrystalline Si may have higher electron mobility and reliability than amorphous Si or poly-Si. As described in detail below with reference to drawings showing processes, the channel layer 102 may be formed not by a deposition process but by patterning a monocrystalline Si wafer. Therefore,

The channel layer 102 may have a cylindrical structure corresponding to the cylindrical structure of a second electrode 176 of the FeCap structure 170. For example, the channel layer 102 may have a cylindrical shape extending in the vertical direction (the Z direction).

Channel layers 102 may be on corresponding word lines 106 by being separated from each other in the second horizontal direction (the Y direction) with the gate insulating layer 104 therebetween. Eventually, the channel layer 102 may be at a cross point position or intersection where the bit line 136 and the word line 106 meet on the X-Y plane.

The word line 106 may include doped polysilicon, a metal, conductive metal nitride, conductive metal silicide, conductive metal oxide, or a combination thereof. For example, the word line 106 may include doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminide (TiAl), titanium aluminum nitride (TiAIN), titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrOx), ruthenium oxide (RuOx), or a combination thereof but is not limited thereto.

The gate insulating layer 104 may be between the channel layer 102 and the word line 106. The gate insulating layer 104 may surround the first sidewall 102s_a and the second sidewall 102s_b of the channel layer 102. In this case, the first sidewall 102s_a and the second sidewall 102s_b of the channel layer 102 may be fully surrounded by the gate insulating layer 104. Unless otherwise noted, the term “surrounding” or “filling” as may be used herein may not require completely surrounding or filling the described elements or layers, but may, for example, refer to partially surrounding or partially filling the described elements or layers, for example, with voids or other spaces throughout. The gate insulating layer 104 may extend in the extending direction (i.e., the second horizontal direction (the Y direction)) of the word line 106 and, in some embodiments, only the first sidewall 102s_a and the second sidewall 102s_b facing respective word lines 106 among the sidewalls of the channel layer 102 may be in contact with the gate insulating layer 104.

The gate insulating layer 104 may also cover the upper surface of the second interlayer insulating layer 120 in addition to the first sidewall 102s_a and the second sidewall 102s_b of the channel layer 102. In this case, the gate insulating layer 104 may extend along the upper surface of the second interlayer insulating layer 120. A cross-section of the gate insulating layer 104, which is perpendicular to the second horizontal direction (the Y direction), may have a U shape turned by 180 degrees (also referred to herein as an upside-down U shape). In this case, one surface of the gate insulating layer 104 may be in contact with the bit line 136, and a portion of the gate insulating layer 104 extending from the one surface may be between a sidewall of the channel layer 102 and the second interlayer insulating layer 120.

In other words, the gate insulating layer 104 may have a first surface in contact with the bit line 136 and a second surface opposite to the first surface and in contact with the etching stop layer 140. In this case, the second surface may longitudinally extend in the second horizontal direction (the Y direction) and partially overlap, in the vertical direction (the Z direction), up to all of a plurality of vertical transistors 100 separated from each other in the second horizontal direction (the Y direction). In detail, the gate insulating layer 104 may overlap, in the vertical direction (the Z direction), the word lines 106 of each of the plurality of vertical transistors 100 separated from each other in the second horizontal direction (the Y direction). Components or layers described with reference to “overlap” in a particular direction may be at least partially obstructed by one another when viewed along a line extending in the particular direction or in a plane perpendicular to the particular direction.

As shown in the cross-section of the memory device 10 taken along line Y-Y′ of FIG. 4, the gate insulating layer 104 is not in contact with a sidewall of the channel layer 102 extending in the second horizontal direction (the Y direction). However, as shown in the cross-section of the memory device 10 taken along line X-X′ of FIG. 4, the gate insulating layer 104 may extend while covering a sidewall of the channel layer 102 extending in the first horizontal direction (the X direction).

The gate insulating layer 104 may extend while covering the upper surface of the second interlayer insulating layer 120 and maintain a conformal thickness. In this case, the upper surface of the gate insulating layer 104 may be coplanar with the upper surface of each channel layer 102.

Each of the gate insulating layer 104 and the channel layer 102 may be in contact with the bit line 136, and the surface of the gate insulating layer 104 in contact with the bit line 136 may be coplanar with the surface of the channel layer 102 in contact with the bit line 136.

In embodiments, the gate insulating layer 104 may include a silicon oxide layer, a silicon oxynitride layer, a high dielectric layer having a higher dielectric constant than the silicon oxide layer (i.e., a high-k dielectric layer), or a combination thereof. The high dielectric layer may include metal oxide or metal oxynitride. For example, a high dielectric layer usable as the gate insulating layer 104 may include hafnium dioxide (HfO₂), hafnium silicate (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), dialuminum trioxide (Al₂O₃), or a combination thereof but is not limited thereto.

The etching stop layer 140 may cover the upper surface of the second interlayer insulating layer 120 and a portion of the upper surface of the gate insulating layer 104. The length of the etching stop layer 140 in the first horizontal direction (the X direction) may be substantially the same as the length of a first electrode 172 in the first horizontal direction (the X direction). The etching stop layer 140 may include a silicon oxide layer, a silicon oxynitride layer, or silicon nitride layer.

The FeCap structure 170 on the channel layer 102 may include n first electrodes 172 stacked by being separated from each other in the vertical direction (the Z direction) from the etching stop layer 140, a second electrode 176 penetrating the n first electrodes 172 in the vertical direction (the Z direction), and a ferroelectric layer 174 surrounding the second electrode 176 and interposed between the n first electrodes 172 and the second electrode 176.

The first electrode 172 and the second electrode 176 may include any one of a doped semiconductor material, a metal, conductive metal nitride, and conductive metal oxide. Herein, the metal may include, for example, Ru, iridium (Ir), Ti, or Ta. The conductive metal nitride may include TiN, TaN, NbN, WN, or the like. The conductive metal oxide may include iridium oxide, niobium oxide, or the like. However, the material of the first electrode 172 and the second electrode 176 is not limited to the materials described above.

The ferroelectric layer 174 may include a ferroelectric material. For example, the ferroelectric layer 174 may include hafnium (Hf)-based oxide. Particularly, the Hf-based oxide may include hafnium oxide (HfO), HfSiO, hafnium oxynitride (HfON), HfSiON, or the like. When the ferroelectric layer 174 includes Hf-based oxide, the ferroelectric layer 174 may include at least one dopant of zirconium (Zr), Si, Al, yttrium (Y), gadolinium (Gd), lanthanum (La), scandium (Sc), and strontium (Sr). However, the material of the ferroelectric layer 174 is not limited to the materials described above.

In addition, the ferroelectric layer 174 may include a single layer or multiple layers. When the ferroelectric layer 174 includes multiple layers, both outermost layers of the ferroelectric layer 174 may include a ferroelectric thin film. As a particular example, the ferroelectric layer 174 may have a three-layer structure of a first ferroelectric thin film, an aluminum oxide (AlO) thin film, and a second ferroelectric thin film. Alternatively, the ferroelectric layer 174 may have a five-layer structure of a first ferroelectric thin film, a first AlO thin film, a second ferroelectric thin film, a second AlO thin film, and a third ferroelectric thin film. However, the multi-layer structure of the ferroelectric layer 174 is not limited to the three-layer structure or the five-layer structure.

The ferroelectric layer 174 may have a tube shape (i.e., a hollow cylindrical shape) having the same vertical length as the second electrode 176. In this case, the inner diameter of the ferroelectric layer 174 may be the same as the diameter of the second electrode 176. The outer diameter of the ferroelectric layer 174 may be less than the width of the channel layer 102 in the first horizontal direction (the X direction) or the second horizontal direction (the Y direction). Therefore, the lower surface of the ferroelectric layer 174 may be fully in contact with the channel layer 102.

As described above, the first electrode 172, the ferroelectric layer 174, and the second electrode 176 may constitute the FeCap structure 170. The FeCap structure 170 may store information indicating 0 or 1 due to a hysteresis characteristic according to dielectric polarization of the ferroelectric layer 174. According to the exact concept or depending on the particular implementation of a capacitor, one first electrode 172 may include one capacitor.

As a reference, a ferroelectric memory (FeRAM) may be identified as a 1Tr1Cap type in which one FeCap is dispatched or otherwise provided for one transistor or a 1Tr type in which a gate dielectric layer of a field-effect transistor (FET) is replaced by a ferroelectric layer, the 1Tr type being similar to an FET. The memory device 10 according to the present embodiment may be of the 1Tr1Cap type. In more detail, in the memory device 10 according to the present embodiment, n capacitors may be dispatched or otherwise provided for one select transistor S-Tr. Therefore, the memory device 10 according to the present embodiment may have a 1TrnCap structure, i.e., a 1TnC structure.

The memory device 10 according to the present embodiment may have the 1TnC structure and also have a pillar structure in which first electrodes 172 lie in a lateral direction, e.g., the first horizontal direction (the X direction) or the second horizontal direction (the Y direction). Particularly, the first electrode 172 having a lying pillar structure in the FeCap structure 170 constitutes a capacitor, and the lying pillar structure may have, for example, a square pillar shape. Accordingly, in the memory device 10 according to the present embodiment, a memory window (MW) per unit area may significantly increase. In addition, compared to a VS-DRAM structure, the memory device 10 according to the present embodiment may be more favorable in terms of process difficulty/distribution in that only the select transistor S-Tr is dispatched and a cell transistor for each layer does not exist.

In addition, in the 1T1C structure or 1TnC structure, an endurance problem of FeRAM (i.e., an FeFET) of a 1Tr structure may be addressed or solved and a problem of stacking channels of monocrystalline Si due to a leakage issue in VS-DRAM may also be addressed or solved. Therefore, in the memory device 10 according to the present embodiment, the 1TnC structure may also reduce or prevent the occurrence of the leakage issue even though poly-Si is used in the channel layer 102. In addition, the memory device 10 according to the present embodiment may have a structure in which first electrodes 172 are separated from each other in the vertical direction (the Z direction). That is, by separating first electrodes 172 from each other in the vertical direction (the Z direction), read disturbance due to a structure in which first electrodes 172 are bundled may be addressed or solved, and accordingly, the reliability of the memory device 10 may be improved.

According to an embodiment, the channel layer 102 may be formed by patterning a first wafer including monocrystalline Si. In this case, a space between channel layers 102 may be filled with the second interlayer insulating layer 120. After forming the channel layer 102, a hole penetrating a plurality of first electrodes 172 is formed in the channel layer 102, and the second electrode 176 longitudinally extending in the vertical direction (the Z direction) while filling the hole may be formed. As shown in FIG. 5, by separating a process of forming the channel layer 102 from a process of forming the second electrode 176, the width of the channel layer 102 in a lateral direction may be different from the width of the hole in the lateral direction. The width of the hole in the lateral direction may be the same as the outer diameter of the ferroelectric layer 174 having a cylindrical shape. Separating a process of patterning the channel layer 102 from a process of forming the second electrode 176 indicates separating a process of forming a space in which the channel layer 102 is to be formed from a process of forming a hole to be filled with the second electrode 176. By separating a process of patterning the channel layer 102 from a process of forming a hole to be filled with the second electrode 176, the second electrode 176 may have a cylindrical shape when the channel layer 102 has a square pillar shape, whereas the second electrode 176 may have a square pillar shape when the channel layer 102 has a cylindrical shape.

In addition, as described in detail below with reference to drawings showing intermediate fabrication processes, by forming the gate insulating layer 104 on a substrate, then attaching the flipped substrate 132 thereto, and turning the same upside down, the gate insulating layer 104 extending in the first horizontal direction (the X direction) may face upward.

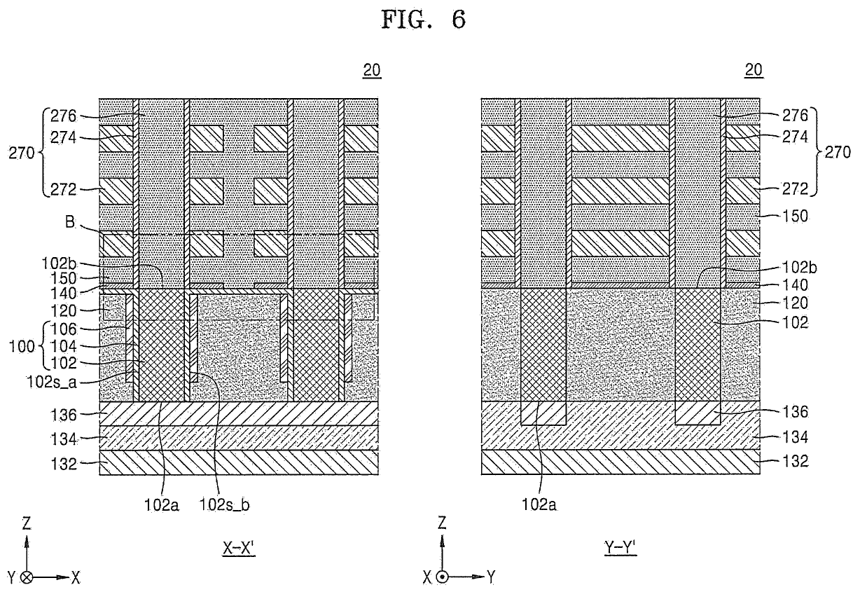

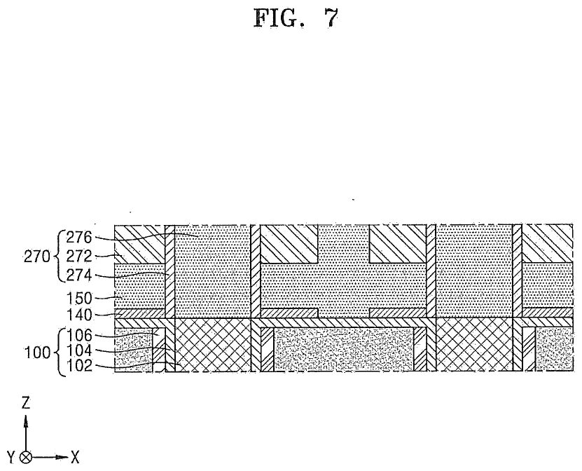

FIG. 6 illustrates cross-sectional views of a memory device 20 according to another embodiment, corresponding to the cross-sectional views of the memory device 10 taken along lines X-X′ and Y-Y′ of the top view of FIG. 3, and FIG. 7 is a magnified cross-sectional view of region B of FIG. 6. The memory device 20 shown in FIGS. 6 and 7 is almost the same as or similar to the memory device 10 shown in FIGS. 4 and 5 except for the widths of a second electrode 276 and a ferroelectric layer 274 in a lateral direction. Therefore, the description of components made with reference to FIGS. 4 and 5 is omitted or simply repeated herein.

Referring to FIGS. 6 and 7, unlike the ferroelectric layer 174 shown in FIGS. 4 and 5, the ferroelectric layer 274 of a FeCap structure 270 may be in contact with the gate insulating layer 104. By separating a process of patterning the channel layer 102 from a process of forming a hole to be filled with the second electrode 276, the width of the channel layer 102 in a lateral direction may be different from the width of the hole in the lateral direction. Therefore, unlike the ferroelectric layer 174 shown in FIGS. 4 and 5, the ferroelectric layer 274 shown in FIGS. 6 and 7 may have an interface between the ferroelectric layer 274 and the gate insulating layer 104 without being in direct contact with the channel layer 102. In addition, the inner diameter of the ferroelectric layer 274 may be the same as the width of the channel layer 102 in the first horizontal direction (the X direction) or the second horizontal direction (the Y direction). In other words, unlike the ferroelectric layer 174 shown in FIGS. 4 and 5, the outer diameter of the ferroelectric layer 274 shown in FIGS. 6 and 7 may be greater than the width of the channel layer 102 in the first horizontal direction (the X direction) or the second horizontal direction (the Y direction).

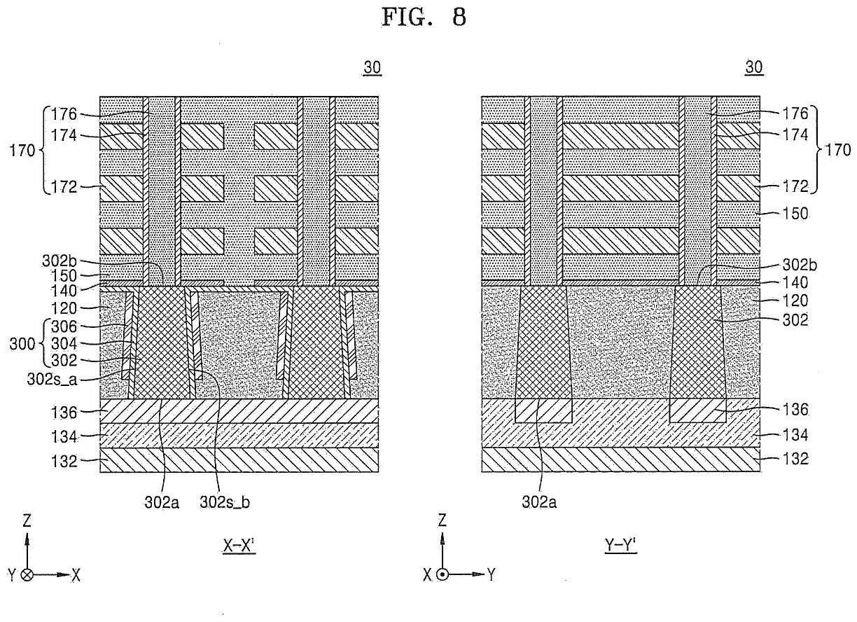

FIG. 8 illustrates cross-sectional views of a memory device 30 according to another embodiment, corresponding to the cross-sectional views of the memory device 10 taken along lines X-X′ and Y-Y′ of the top view of FIG. 3. The memory device 30 shown in FIG. 8 is almost the same as or similar to the memory device 10 shown in FIGS. 4 and 5 except that a channel layer 302 has a tapered shape with the lateral directional width of the channel layer 302 gradually increasing toward the bit line 136. Therefore, the description of components made with reference to FIGS. 4 and 5 is omitted or simply repeated herein. Hereinafter, a description is made with reference to FIG. 8.

As described in detail below with reference to drawings showing processes, the channel layer 302 may be formed by patterning the monocrystalline Si wafer 101 (see FIG. 10B). By separating a process of patterning the channel layer 302 from a process of forming a hole to be filled with the second electrode 176, a vertical direction in which an etching process of forming the channel layer 302 is performed may be different from a vertical direction in which an etching process of forming the hole to be filled with the second electrode 176 is performed. Therefore, the channel layer 302 may have a tapered shape with the lateral directional width of the channel layer 302 gradually increasing toward the bit line 136.

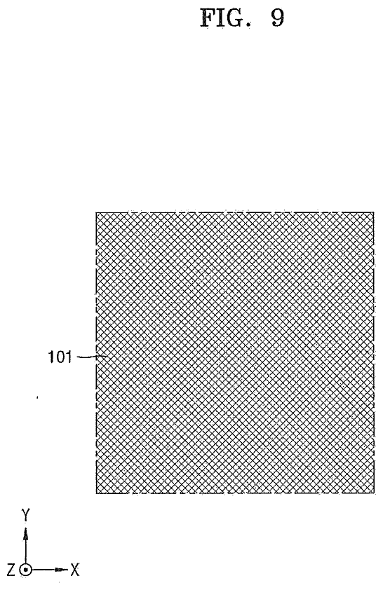

FIGS. 9, 10A to 10C, 11A to 11C, 12A to 12C, 13A to 13C, 14A to 14C, and 15A to 15C are top views and cross-sectional views illustrating, in order, a method of manufacturing a memory device, according to an embodiment. Particularly, FIGS. 10B, 11B, 12B, 13B, 14B, and 15B are cross-sectional views of the memory device taken along line X-X′ of the top views of FIGS. 10A, 11A, 12A, 13A, 14A, and 15A, respectively, and FIGS. 10C, 11C, 12C, 13C, 14C, and 15C are cross-sectional views of the memory device taken along line Y-Y′ of the top views of FIGS. 10A, 11A, 12A, 13A, 14A, and 15A, respectively.

Referring to FIG. 9, the method of manufacturing a memory device, according to an embodiment, may include preparing the monocrystalline Si wafer 101. Monocrystalline Si has Si atoms regularly arranged, and every two Si atoms are joined with a covalent bond, and thus, the monocrystalline Si may have higher electron mobility and reliability than amorphous Si or poly-Si.

Referring to FIGS. 10A to 10C, the method of manufacturing a memory device, according to an embodiment, may include forming a first trench TR1 by etching the monocrystalline Si wafer 101. Herein, the first trench TR1 may be formed to extend in the first horizontal direction (the X direction) with a width in the second horizontal direction (the Y direction). Thereafter, the second interlayer insulating layer 120 may be formed by filling the first trench TR1 with an insulating material. After forming the second interlayer insulating layer 120, a sacrificial insulating layer SID conformally covering the lower surface of the second interlayer insulating layer 120 and the lower surface of the monocrystalline Si wafer 101 may be formed, and a sacrificial substrate SS covering the lower surface of the sacrificial insulating layer SID may be attached to the sacrificial insulating layer SID. The sacrificial insulating layer SID and the sacrificial substrate SS may be formed to have a planar or plate shape along the lower surface of the second interlayer insulating layer 120 and the lower surface of the monocrystalline Si wafer 101.

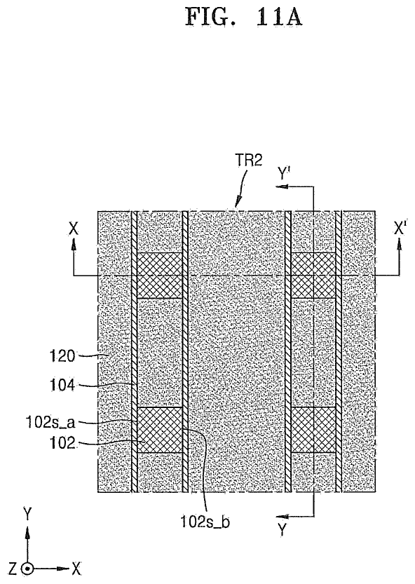

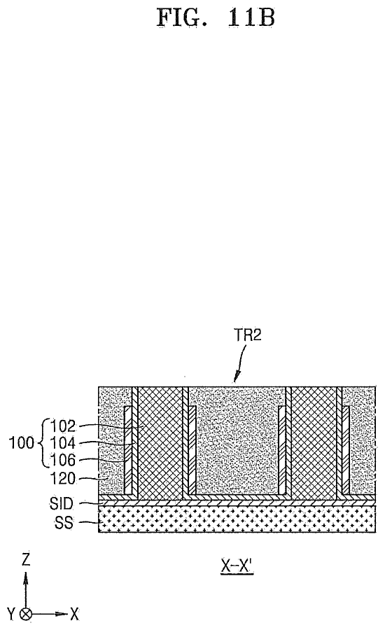

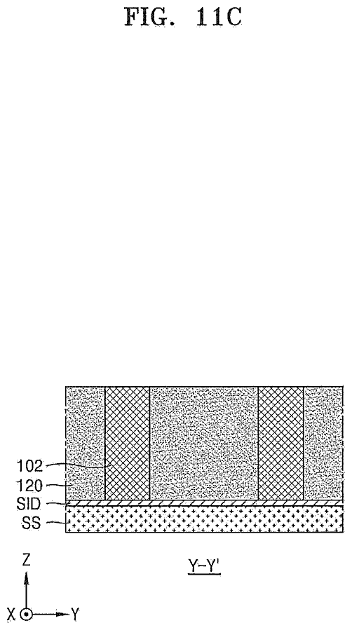

Referring to FIGS. 11A to 11C, the method of manufacturing a memory device, according to an embodiment, may include patterning the channel layer 102 by forming a second trench TR2 extending in the second horizontal direction (the Y direction). The second trench TR2 may be filled with an insulating material to form an insulating layer integrated with the second interlayer insulating layer 120 formed in the process shown in FIGS. 10A to 10C. The insulating layer formed in the process shown in FIGS. 11A to 11C may also be defined as the second interlayer insulating layer 120. In addition, after patterning the channel layer 102, the gate insulating layer 104 in contact with the first sidewall 102s_a and the second sidewall 102s_b of the channel layer 102 may be formed. The gate insulating layer 104 may be formed to longitudinally extend in the second horizontal direction (the Y direction) with a constant or substantially uniform width in the first horizontal direction (the X direction). The gate insulating layer 104 may be formed to be in full contact with each of the first sidewall 102s_a and the second sidewall 102s_b of the channel layer 102.

After forming the gate insulating layer 104, word lines 106 in contact with the gate insulating layer 104 and separated from each other in the second horizontal direction (the Y direction) with the channel layer 102 therebetween may be formed. The word line 106 may longitudinally extend in the first horizontal direction (the X direction). The lower surface and one side surface of the word line 106 may be in contact with the gate insulating layer 104, and the other side surface of the word line 106 opposite to the one side surface may be in contact with the second interlayer insulating layer 120.

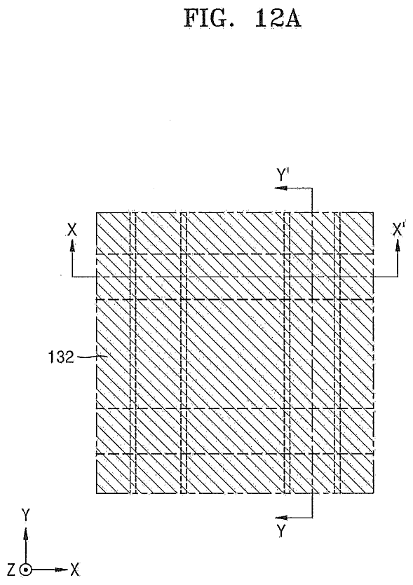

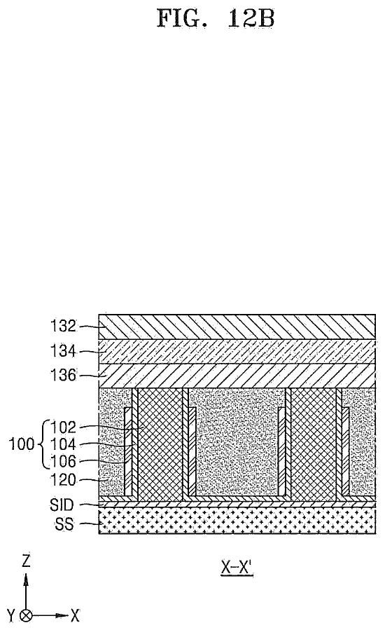

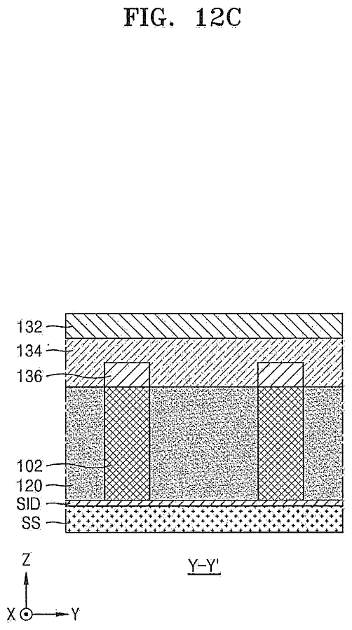

Referring to FIGS. 12A to 12C, the bit line 136 and the first interlayer insulating layer 134 may be formed on the channel layer 102 in the vertical direction (the Z direction), and the flipped substrate 132 may be attached to the first interlayer insulating layer 134.

The bit line 136 may be formed to correspond to the channel layer 102. Bit lines 136 may be formed to be separated from each other in the second horizontal direction (the Y direction) and longitudinally extend in the first horizontal direction (the X direction). The bit line 136 may be formed to be in contact with the channel layer 102 and the gate insulating layer 104.

The first interlayer insulating layer 134 may be formed to bury the bit line 136 therein. Herein, the first interlayer insulating layer 134 may be formed to be in contact with the bit line 136 and the second interlayer insulating layer 120. A cross-section of the first interlayer insulating layer 134, which is perpendicular to the second horizontal direction (the Y direction), may have a concave-convex shape having a plurality of grooves. Respective bit lines 136 may be buried in each of the plurality of grooves of the first interlayer insulating layer 134.

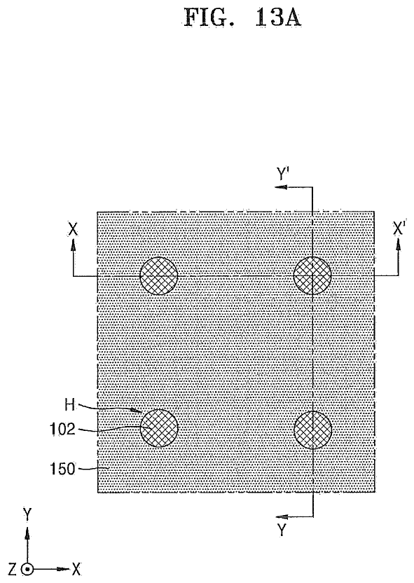

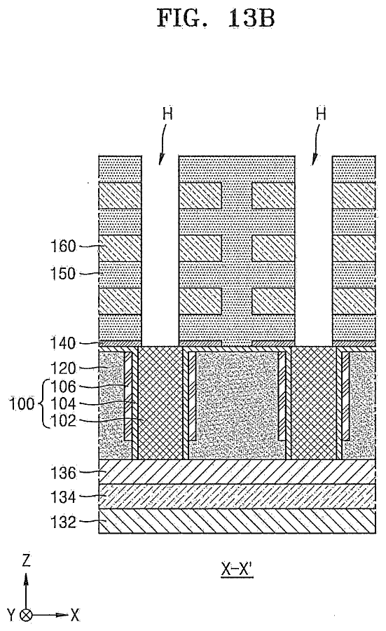

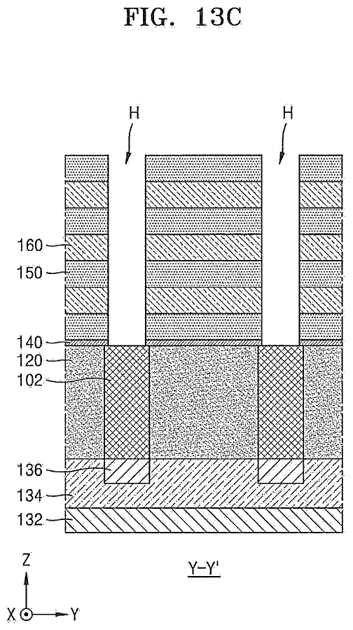

Referring to FIGS. 13A to 13C, after turning the flipped substrate 132 upside down, the etching stop layer 140, the insulating layer 150, and a plurality of sacrificial layers 160 may be formed on the channel layer 102. The etching stop layer 140 may be formed to cover the upper surface of the channel layer 102 and the upper surface of the gate insulating layer 104.

Thereafter, insulating layers 150 and sacrificial layers 160 are alternately stacked on the etching stop layer 140 in the vertical direction (the Z direction). The insulating layer 150 and the sacrificial layer 160 may include materials having an etch selectivity with respect to each other. For example, the insulating layer 150 may include an oxide layer, such as an SiO₂ layer, and the sacrificial layer 160 may include a nitride layer, such as a silicon nitride (SiNx) layer. However, the materials of the insulating layer 150 and the sacrificial layer 160 are not limited to the materials described above. In addition, the etching stop layer 140 may include a material having an etching selectivity with respect to the insulating layer 150 and the sacrificial layer 160. However, because the insulating layer 150 is formed immediately or directly on the etching stop layer 140, according to an embodiment, the etching stop layer 140 may include a material, e.g., a nitride layer, having an etching selectivity with respect to the insulating layer 150.

After alternately stacking the insulating layers 150 and the sacrificial layers 160 on the etching stop layer 140, a hole H penetrating the etching stop layer 140, the insulating layers 150, and the sacrificial layers 160 in the vertical direction (the Z direction) may be formed. The hole H may be formed through an etching process. Herein, the hole H may be formed to be aligned with the upper surface of the channel layer 102. Although FIGS. 13B and 13C show that the hole H has a constant diameter in the vertical direction (the Z direction), according to an embodiment, the hole H may have a tapered shape with a diameter decreasing toward the channel layer 102. By forming the hole H, in the top view as shown in FIG. 13A, a portion of the channel layer 102 may be exposed from the upper surface of the uppermost insulating layer 150 through the hole H.

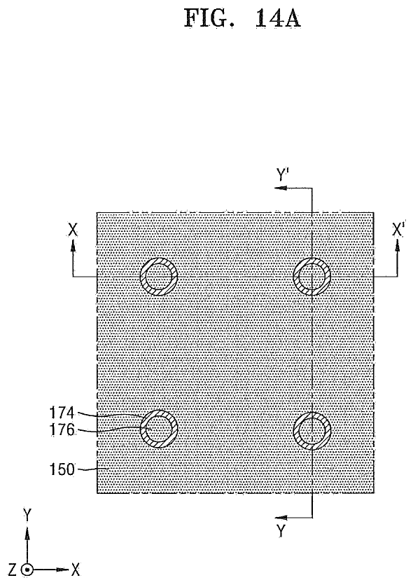

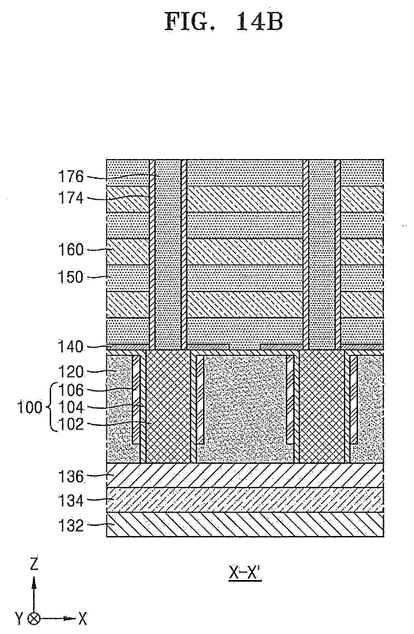

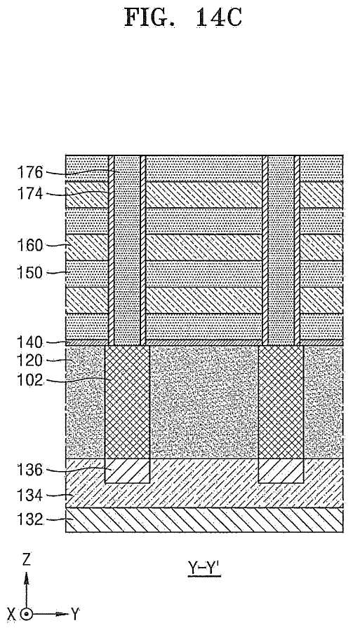

Referring to FIGS. 14A to 14C, the method of manufacturing a memory device, according to an embodiment, may include forming the second electrode 176 filling the hole H penetrating, in the vertical direction (the Z direction), the insulating layers 150 and the sacrificial layers 160 alternately staked, and the ferroelectric layer 174 surrounding the second electrode 176. The second electrode 176 and the ferroelectric layer 174 may be formed by a deposition process. The ferroelectric layer 174 may be formed to conformally cover the surface of the second electrode 176. According to an embodiment, the ferroelectric layer 174 may be formed by an atomic layer deposition (ALD) process but is not necessarily limited thereto.

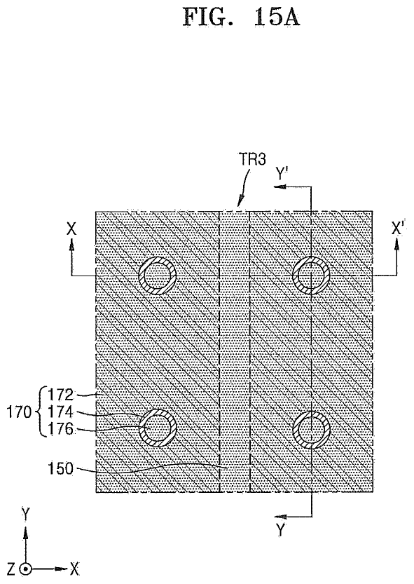

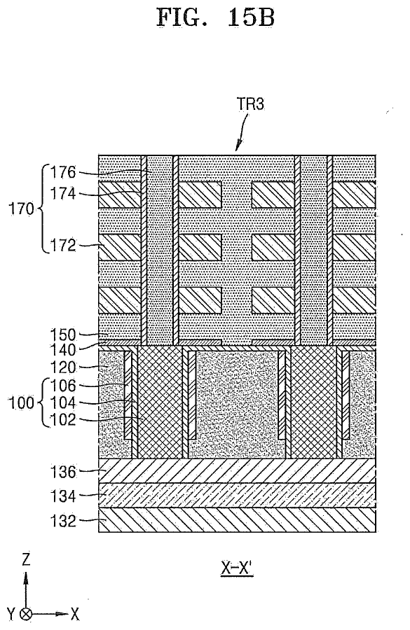

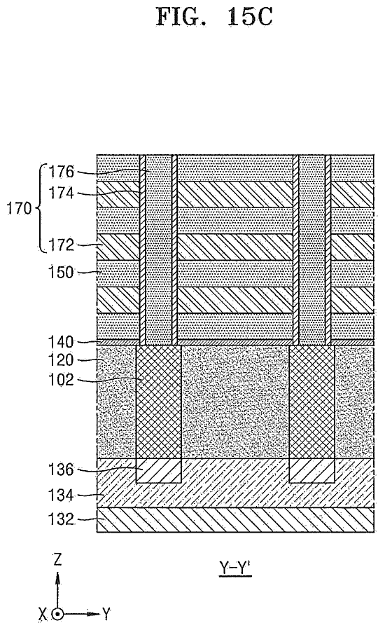

Referring to FIGS. 15A to 15C, the method of manufacturing a memory device, according to an embodiment, may include removing the sacrificial layers 160 shown in FIGS. 14B and 14C and then forming first electrodes 172 in spaces in which the sacrificial layers 160 were removed. Therefore, the first electrodes 172 may be stacked by being separated from each other in the vertical direction (the Z direction). By forming the first electrodes 172, the FeCap structure 170 is completed. After forming the first electrodes 172, a third trench TR3 extending in the vertical direction (the Z direction) may be formed between every two of a plurality of channel layers 102 separated from each other in the first horizontal direction (the X direction). The third trench TR3 may be formed to penetrate the first electrodes 172. After forming the third trench TR3, the third trench TR3 may be filled with an insulating material to form an insulating layer. By filling the third trench TR3 with the insulating material, the first electrodes 172 separated from each other in the first horizontal direction (the X direction) may be electrically isolated from each other.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

While the inventive concept has been particularly shown and described with reference to embodiments thereof, it will be understood that various changes in form and details may be made therein without departing from the spirit and scope of the following claims.

What is claimed is:

1. A memory device comprising:
a substrate;
a plurality of bit lines on the substrate and extending in a first horizontal direction and separated from each other in a second horizontal direction that intersects the first horizontal direction;
a plurality of channel layers extending in a vertical direction that is perpendicular to an upper surface of the substrate on the plurality of bit lines;
a plurality of word lines on a bit line among the plurality of bit lines in the vertical direction, extending in the second horizontal direction, and separated from each other in the first horizontal direction;
an interlayer insulating layer between the plurality of channel layers;
a gate insulating layer between a channel layer among the plurality of channel layers and a word line among the plurality of word lines and on an upper surface of the interlayer insulating layer opposite the substrate; and
a ferroelectric capacitor structure on the channel layer in the vertical direction and comprising a plurality of first electrodes separated from each other in the vertical direction.

2. The memory device of claim 1, further comprising:
an etching stop layer on the channel layer, the interlayer insulating layer, and the gate insulating layer.

3. The memory device of claim 1, wherein the channel layer comprises monocrystalline silicon.

4. The memory device of claim 1, wherein the ferroelectric capacitor structure further comprises:
a second electrode penetrating the plurality of first electrodes in the vertical direction; and
a dielectric layer extending around the second electrode and between each of the plurality of first electrodes and the second electrode.

5. The memory device of claim 4, wherein the second electrode has a cylindrical shape.

6. The memory device of claim 4, wherein the dielectric layer has a hollow cylindrical shape, and an outer diameter of the dielectric layer is less than a width of the channel layer in the first horizontal direction or the second horizontal direction.

7. The memory device of claim 1, wherein a cross-section of the gate insulating layer, in a direction perpendicular to the second horizontal direction, has an upside-down U shape.

8. The memory device of claim 1, wherein the gate insulating layer extends on a first sidewall of the channel layer extending in the first horizontal direction, and wherein the gate insulating layer is not contact with a second sidewall of the channel layer extending in the second horizontal direction.

9. The memory device of claim 1, wherein an upper surface of the gate insulating layer, which is opposite the substrate, is coplanar with an upper surface of each of the plurality of channel layers.

10. The memory device of claim 1, wherein the gate insulating layer and each of the plurality of channel layers are in contact with the bit line, and
wherein a surface of the gate insulating layer in contact with the bit line is coplanar with a surface of each of the plurality of channel layers in contact with the bit line.

11. A memory device comprising:
a substrate;
a plurality of bit lines on the substrate and extending in a first horizontal direction and separated from each other in a second horizontal direction that intersects the first horizontal direction;
a plurality of vertical transistors each comprising word lines on the plurality of bit lines in a vertical direction that is perpendicular to the substrate, wherein the word lines extend in the second horizontal direction and are separated from each other in the first horizontal direction, a channel layer extending in the vertical direction on the substrate, and a gate insulating layer between one of the word lines and the channel layer;
an interlayer insulating layer between the plurality of vertical transistors;
an etching stop layer on the gate insulating layer and the interlayer insulating layer; and
a ferroelectric capacitor structure on each of the plurality of vertical transistors in the vertical direction and comprising two or more capacitors,
wherein the gate insulating layer extends along an upper surface of the interlayer insulating layer and on an upper surface of the one of the word lines opposite the substrate.

12. The memory device of claim 11, wherein the ferroelectric capacitor structure comprises:
two or more first electrodes stacked on the etching stop layer and separated from each other in the vertical direction;
a second electrode penetrating the two or more first electrodes in the vertical direction; and
a ferroelectric layer extending around the second electrode and between each of the two or more first electrodes and the second electrode.

13. The memory device of claim 12, wherein the channel layer comprises:
a first surface in contact with one of the bit lines; and
a second surface opposite to the first surface and in contact with the second electrode,
wherein the second surface is in contact with the etching stop layer and the ferroelectric layer.

14. The memory device of claim 12, wherein the channel layer comprises:
a first surface in contact with one of the bit lines; and
a second surface opposite to the first surface and in contact with the second electrode,
wherein the second surface is not in contact with the ferroelectric layer.

15. The memory device of claim 12, wherein each of a width of the channel layer in the first horizontal direction and a width of the channel layer in the second horizontal direction is substantially equal to a diameter of the second electrode.

16. The memory device of claim 11, wherein respective widths of the channel layer in the first horizontal direction and in the second horizontal direction decrease in the vertical direction toward the ferroelectric capacitor structure.

17. The memory device of claim 11, wherein the channel layer comprises monocrystalline silicon (c-Si).

18. A memory device comprising:
a substrate;
a first interlayer insulating layer on the substrate;
a plurality of bit lines buried in the first interlayer insulating layer, extending in a first horizontal direction, and separated from each other in a second horizontal direction that intersects the first horizontal direction;
a plurality of vertical transistors comprising a plurality of channel layers extending in a vertical direction on a bit line among the plurality of bit lines, a word line separated from the plurality of channel layers in the first horizontal direction and extending in the second horizontal direction, and a gate insulating layer between each of the plurality of channel layers and the word line and extending along a sidewall of each of the plurality of channel layers;
a second interlayer insulating layer between the plurality of vertical transistors on the bit line;
an etching stop layer on the gate insulating layer and the second interlayer insulating layer; and
a plurality of ferroelectric capacitor structures on the plurality of vertical transistors in the vertical direction, and each of the plurality of ferroelectric capacitor structures comprising a plurality of first electrodes stacked on and separated from each other on the second interlayer insulating layer in the vertical direction, a hollow ferroelectric layer conformally extending along a sidewall of a hole penetrating the plurality of first electrodes in the vertical direction, and a second electrode extending in the vertical direction inside the hollow ferroelectric layer,
wherein the gate insulating layer has a first surface in contact with the bit line and a second surface opposite to the first surface and in contact with the etching stop layer, the second surface longitudinally extends the second horizontal direction, and the second surface overlaps, in the vertical direction, the plurality of vertical transistors separated from each other in the second horizontal direction.

19. The memory device of claim 18, wherein a cross-section of the gate insulating layer, in a direction perpendicular to the second horizontal direction, has an upside-down U shape.

20. The memory device of claim 18, wherein the sidewall of each of the plurality of channel layers is a first sidewall and each of the plurality of channel layers comprises a second sidewall, wherein the gate insulating layer extends on the first sidewall, which extends in the first horizontal direction, and
wherein the gate insulating layer is not contact with the second sidewall, which extends in the second horizontal direction.
